(19) United States
(12) Patent Application Publication
(10) Pub. No.: US 2025/0092284 A1
(43) Pub. Date: Mar. 20, 2025

(54) POLISHING COMPOSITION AND SURFACE TREATMENT METHOD

(71) Applicant: FUJIMI INCORPORATED, Kiyosu-shi (JP)

(72) Inventor: Toshio SHINODA, Tongluo Township (TW)

(73) Assignee: FUJIMI INCORPORATED, Kiyosu-shi (JP)

(21) Appl. No.: 18/808,773

(22) Filed: Aug. 19, 2024

(30) Foreign Application Priority Data
Sep. 14, 2023 (JP) 2023-148913

(51) Int. Cl. C09G 1/02; B24B 37/04; H01L 21/306

(52) U.S. Cl. CPC C09G 1/02; B24B 37/044; H01L 21/30625

(57) ABSTRACT

Means for effectively removing hafnium oxide can be provided. A polishing composition contains (a) an anionic abrasive, (b) a nitrogen-containing additive, and (c) a dispersing medium, wherein the pH of the polishing composition is 2 or more and less than 5, and the (b) nitrogen-containing additive contains at least one selected from the group consisting of the following (i), the following (ii), and the following (iii); (i) a compound selected from the group consisting of a guanidine compound having a specific structure, an amidine compound having a specific structure, and salts thereof; (ii) a cyclic amino acid; and (iii) a sulfonic acid compound having an amino group.

### CROSS-REFERENCE TO RELATED APPLICATION

The present application is based on Japanese Patent Application No. 2023-148913 filed on Sep. 14, 2023, the disclosure content of which is incorporated herein by reference in its entirety.

### BACKGROUND

### 1. Technical Field

The present invention relates to a polishing composition and a surface treatment method using the polishing composition.

### 2. Description of Related Arts

In the current semiconductor industry, the development of technology of semiconductor manufacturing processes is continuously advancing. Chemical mechanical polishing (CMP) technology for planarizing the surface of a semiconductor is widely used in semiconductor manufacturing processes. Examples of CMP include a method of planarizing the surface of an object to be polished such as a semiconductor substrate using a polishing composition (slurry) containing abrasive grains such as silica, alumina, or ceria and an additive such as an anticorrosive or a surfactant. Examples of the object to be polished include those of silicon, polysilicon, a silicon oxide film (silicon oxide), silicon nitride, a metal, a metal oxide, a metal nitride, and the like.

Various proposals have been made so far for polishing compositions corresponding to respective objects to be polished.

JP 2020-26473 A (corresponding to US 2020/048497 A) discloses a polishing composition used for polishing an object to be polished containing a silicon nitride film. The polishing composition contains abrasive grains, an anionic surfactant, and a dispersing medium, and has a pH of less than 7. With the polishing composition, the object to be polished containing the silicon nitride film can be polished at a high polishing removal rate, and the amount of particle residue on the object to be polished can be reduced.

JP 2012-40671 A (corresponding to US 2013/146804 A) discloses a polishing composition capable of polishing silicon nitride at a higher removal rate. The polishing composition contains colloidal silica on which an organic acid is immobilized, and has a pH of 6 or less.

JP 2003-224092 A (corresponding to US 2003/157804 A) discloses a composition for chemically and mechanically polishing a metal and a dielectric structure at a high copper removal rate. The composition contains a cationically modified silica sol and an oxidizing agent, and has a pH of 2.5 to 6. The composition can achieve a higher metal removal rate and a higher selectivity for the metal: barrier layer.

JP 2013-179303 A (corresponding to US 2010/216309 A) discloses a polishing liquid capable of improving a polishing removal rate of a ruthenium layer. The polishing liquid contains an oxidizing agent, abrasive particles, water, and a guanidine compound or a salt thereof.

### SUMMARY

Hafnium oxide has a high dielectric constant and is used as an insulating film material of a semiconductor. In addition, since it has been found that hafnium oxide has ferroelectric properties, application to a semiconductor is attracted attention, and improvement in polishing removal rate of a hafnium oxide film is expected in semiconductor manufacturing. The polishing composition described in the above patent documents can realize polishing at a high polishing removal rate of silicon nitride, copper, or ruthenium, but there is no disclosures or suggestions about a polishing composition used for polishing a hafnium oxide film, and the requirements of users have not been satisfied.

In view of the above, an object of the present invention is to provide means capable of effectively removing hafnium oxide.

As a result of repeated studies, the inventor of the present application has found that the above problem can be solved by the following (exemplary only and not limited thereto) embodiment of the present invention.

A polishing composition according to a first embodiment of the present invention is a polishing composition containing (a) an anionic abrasive, (b) a nitrogen-containing additive, and (c) a dispersing medium, in which
a pH of the polishing composition is 2 or more and less than 5, and
the (b) nitrogen-containing additive contains at least one selected from the group consisting of (i), (ii), and (iii). Here, (i), (ii), and (iii) are as follows.
(i) A compound selected from the group consisting of a guanidine compound represented by Formula (I) below, an amidine compound represented by Formula (II) below, and salts thereof;

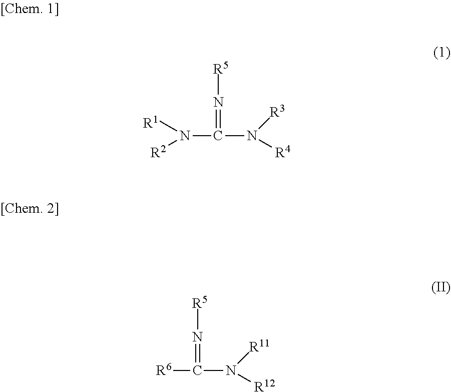

wherein
R¹, R², R³, R⁴, R¹¹ and R¹² are each independently a hydrogen atom, a cyano group, a nitro group, a nitroso group, an amino group, an aminoalkyl group, an alkyl group, an alkoxy group, an aryl group, a heterocyclic group, a —C(═O)-alkyl group, or a —C(═O)—O-alkyl group,
R⁶ is a hydrogen atom, a cyano group, a nitro group, a nitroso group, an aminoalkyl group, an alkyl group, an alkoxy group, an aryl group, a heterocyclic group, a —C(═O)-alkyl group, or a —C(═O)—O-alkyl group,
the aryl group or the heterocyclic group may be optionally substituted with one or more groups independently selected from a nitro group, a nitroso group, an amino group, or an alkyl group, and
R⁵'s are each independently a hydrogen atom, an alkyl group, or an alkoxy group;
(ii) a cyclic amino acid; and
(iii) a sulfonic acid compound having an amino group.

A polishing composition according to a second embodiment of the present invention is the polishing composition according to the first embodiment, in which the R¹, the R², and the R⁶ are each independently a hydrogen atom, an alkyl group, or an alkoxy group.

A polishing composition according to a third embodiment of the present invention is the polishing composition according to the first embodiment or the second embodiment, in which the (b) nitrogen-containing additive is the guanidine compound represented by the Formula (I), the amidine compound represented by the Formula (II), or a salt thereof, and the salt is a carbonate, a hydrochloride, a sulfate, a phosphate, or a nitrate.

A polishing composition according to a fourth embodiment of the present invention is the polishing composition according to any one of the first embodiment to the third embodiment, in which the (b) nitrogen-containing additive is the guanidine compound represented by the Formula (I), and the R¹ and the R² are each independently a hydrogen atom, an alkyl group, or an alkoxy group.

A polishing composition according to a fifth embodiment of the present invention is the polishing composition according to the first embodiment or the second embodiment, in which the (ii) cyclic amino acid has a structure represented by Formula (III) below;

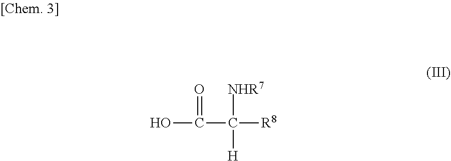

wherein
R⁷ is a hydrogen atom, an alkyl group or an alkoxy group, R⁸ is —(CH₂)ₚ-Q, p is 0, 1 or 2, Q is an aryl group or a heterocyclic group, and the aryl group or the heterocyclic group may be optionally substituted with one or more —OH's or one or more hydroxyalkyl groups, or
R⁷ and R⁸, and the carbon and nitrogen atoms bonded thereto together form a 5- to 6-membered heterocyclic ring.

A polishing composition according to a sixth embodiment of the present invention is the polishing composition according to the first embodiment, the second embodiment, or the fifth embodiment, in which the (ii) cyclic amino acid is proline, tryptophan, or histidine.

A polishing composition according to a seventh embodiment of the present invention is the polishing composition according to the first embodiment, the second embodiment, the fifth embodiment, or the sixth embodiment, in which the (iii) sulfonic acid compound having an amino group is a sulfonic acid compound having a primary amide group, a secondary amide group, or a tertiary amide group.

A polishing composition according to an eighth embodiment of the present invention is the polishing composition according to the first embodiment, the second embodiment, the fifth embodiment, the sixth embodiment, or the seventh embodiment, in which the (iii) sulfonic acid compound having an amino group has a structure represented by Formula (IV) below;

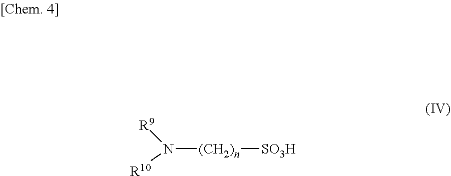

wherein
n is 1, 2, 3, or 4,
R⁹ and R¹⁰ are each independently a hydrogen atom, an amino group, an aminoalkyl group, an alkyl group, or a hydroxyalkyl group, or
R⁹ and R¹⁰, and the nitrogen atom bonded thereto together form a 5- to 6-membered heterocyclic ring and the 5- to 6-membered heterocyclic ring may be optionally substituted with one or more —OH's or one or more hydroxyalkyl groups.

A polishing composition according to a ninth embodiment of the present invention is the polishing composition according to any one of the first embodiment to the eighth embodiment, in which the (a) anionic abrasive is surface-modified colloidal silica.

A polishing composition according to a tenth embodiment of the present invention is the polishing composition according to any one of the first embodiment to the ninth embodiment, in which the (c) dispersing medium is water.

A polishing composition according to an eleventh embodiment of the present invention is the polishing composition according to any one of the first embodiment to the tenth embodiment, the polishing composition further containing (d) a surfactant.

A polishing composition according to a twelfth embodiment of the present invention is the polishing composition according to the eleventh embodiment, in which the (d) surfactant is polyether.

A polishing composition according to a thirteenth embodiment of the present invention is the polishing composition according to the eleventh embodiment or the twelfth embodiment, in which the (d) surfactant is at least one selected from the group consisting of polyethylene glycol, polypropylene glycol, polyglycerol, and copolymers thereof.

A polishing composition according to the fourteenth embodiment of the present invention is the polishing composition according to any one of the first embodiment to the thirteenth embodiment, in which a use amount (content) of the (a) anionic abrasive with respect to a total mass of the polishing composition is 0.1 to 15 mass %.

A polishing composition according to a fifteenth embodiment of the present invention is the polishing composition according to any one of the first embodiment to the fourteenth embodiment, in which a use amount (content) of the (b) nitrogen-containing additive with respect to a total mass of the polishing composition is 0.005 to 5 mass %.

A surface treatment method according to a sixteenth embodiment of the present invention is a surface treatment method including a process of performing a surface treatment on an object to be treated using the polishing composition according to any one of the first embodiment to the fifteenth embodiment.

A surface treatment method according to a seventeenth embodiment of the present invention is the surface treatment method according to the sixteenth embodiment, in which the object to be treated contains hafnium oxide.

A surface treatment method according to an eighteenth embodiment of the present invention is the surface treatment method according to the sixteenth embodiment or the seventeenth embodiment, in which the object to be treated contains hafnium oxide and a silicon-based material.

A surface treatment method according to a nineteenth embodiment of the present invention is the surface treatment method according to any one of the sixteenth to the eighteenth embodiment, in which the surface treatment is at least one selected from the group consisting of a flattening treatment, a selective removal treatment, and a cleaning treatment.

A surface treatment apparatus according to a twentieth embodiment of the present invention is a surface treatment apparatus including a mechanism that performs a surface treatment on an object to be treated using the polishing composition according to any one of the first embodiment to the fifteenth embodiment.

A surface treatment apparatus according to a twenty-first embodiment of the present invention is the surface treatment method according to the twentieth embodiment, in which the object to be treated contains hafnium oxide.

A surface treatment apparatus according to a twenty-second embodiment of the present invention is the surface treatment apparatus according to the twentieth embodiment or the twenty-first embodiment, in which the object to be treated contains hafnium oxide and a silicon-based material.

A surface treatment apparatus according to a twenty-third embodiment of the present invention is the surface treatment method according to any one of the twentieth embodiment to the twenty-second embodiment, in which the surface treatment is at least one selected from the group consisting of a flattening treatment, a selective removal treatment, and a cleaning treatment.

A semiconductor manufacturing method according to a twenty-fourth embodiment of the present invention is a semiconductor manufacturing method including a process of performing the surface treatment method according to any one of the sixteenth embodiment to the nineteenth embodiment.

A semiconductor manufacturing facility according to a twenty-fifth embodiment of the present invention is a semiconductor manufacturing facility including the surface treatment apparatus according to any one of the twentieth embodiment to the twenty-third embodiment.

A use according to a twenty-sixth of the present invention is a use for surface treatment of the polishing composition according to any one of the first embodiment to the fifteenth embodiment.

A use according to a twenty-seventh embodiment of the present invention is the use according to the twenty-sixth embodiment, in which the object to be treated in the surface treatment contains hafnium oxide.

A use according to a twenty-eighth embodiment of the present invention is the use according to the twenty-sixth embodiment or the twenty-seventh embodiment, in which the object to be treated in the surface treatment contains hafnium oxide and a silicon-based material.

A use according to a twenty-ninth embodiment of the present invention is the use according to any one of the twenty-sixth embodiment to the twenty-eighth embodiment, in which the surface treatment is at least one selected from the group consisting of a flattening treatment, a selective removal treatment, and a cleaning treatment.

However, the present invention is not limited only to the first embodiment to the twenty-ninth embodiment. Although examples of embodiments of the present invention have been illustrated above, it is clear that the scope of the present invention should be interpreted by the appended claims.

### DETAILED DESCRIPTION

Hereinafter, an embodiment according to the present invention will be described in detail. In the present specification, “X to Y” indicating a range means “X or more and Y or less”. In a case where a plurality of “X to Y” are described, for example, in a case where “X1 to Y1, or X2 to Y2” is described, the disclosure with each numerical value as the upper limit, the disclosure with each numerical value as the lower limit, and a combination of the upper limit and the lower limit are all disclosed (that is, these provide a legitimate bases of amendments). Specifically, all of the amendment of X1 or more, the amendment of Y2 or less, the amendment of X1 or less, the amendment of Y2 or more, the amendment of X1 to X2, and the amendment of X1 to Y2 must be regarded as legitimate. In addition, unless otherwise specified, operations and measurements of physical properties and the like are performed under the conditions of room temperature (20 to 25° C.)/relative humidity 40 to 50% RH.

### <Polishing Composition>

One aspect of the present invention relates to a polishing composition containing (a) an anionic abrasive, (b) a nitrogen-containing additive, and (c) a dispersing medium, and having a pH of 2 or more and less than 5. In the present aspect, the (b) nitrogen-containing additive contains at least one selected from the group consisting of the following (i), the following (ii), and the following (iii).
(i) A compound selected from the group consisting of a guanidine compound represented by Formula (I) below, an amidine compound represented by Formula (II) below, and salts thereof;

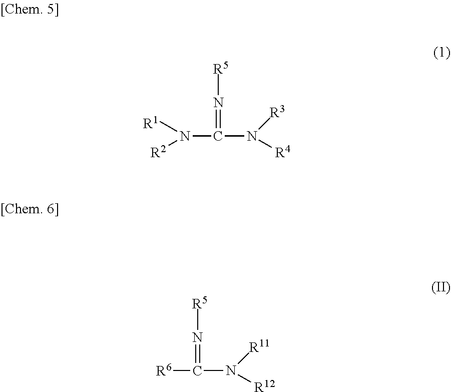

wherein
R¹, R², R³, R⁴, R¹¹ and R¹² are each independently a hydrogen atom, a cyano group, a nitro group, a nitroso group, an amino group, an aminoalkyl group, an alkyl group, an alkoxy group, an aryl group, a heterocyclic group, a —C(═O)-alkyl group, or a —C(═O)—O-alkyl group,
R⁶ is a hydrogen atom, a cyano group, a nitro group, a nitroso group, an aminoalkyl group, an alkyl group, an alkoxy group, an aryl group, a heterocyclic group, a —C(═O)-alkyl group, or a —C(═O)—O-alkyl group,
the aryl group or the heterocyclic group is optionally substituted with one or more groups independently selected from a nitro group, a nitroso group, an amino group, or an alkyl group, and
R⁵'s are each independently a hydrogen atom, an alkyl group, or an alkoxy group;
(ii) a cyclic amino acid; and
(iii) a sulfonic acid compound having an amino group.

According to the present aspect, it is possible to provide a polishing composition and a surface treatment method capable of effectively removing hafnium oxide. In some embodiments, a polishing composition and a method can be provided that can selectively remove hafnium oxide relative to a silicon-based material (polysilicon, silicon-germanium (SiGe), silicon oxide produced from tetraethyl orthosilicate as a raw material (in this industry, this material is called “TEOS”, in this specification, “TEOS” has this meaning), or the like).

Specifically, when polishing is performed using the polishing composition of these embodiments, hafnium oxide can be selectively removed relative to the silicon-based material. In a preferred embodiment, since the removal rate of the silicon-based material can be further reduced, the selection ratio of hafnium oxide/silicon-based material can be improved.

Furthermore, since the removal rate of the silicon-based material can be significantly reduced, it can also be expected to reduce damage to the silicon-based material as much as possible.

### [(a) Anionic Abrasive]

The polishing composition according to the present aspect contains an anionic abrasive. The anionic abrasive is an abrasive that is negatively charged and exhibits a negative potential value (mV) in the zeta potential plot. In the present specification, the anionic abrasive may be an abrasive that exhibits a negative potential value (mV) at any pH in the zeta potential plot. The anionic abrasive can be formed by adding an anionic group on the surface of the nonionic abrasive. This modification to produce the anionic abrasive may be by a chemical bond or by physically forming a plurality of self-assembled monolayers on the surface of the abrasive, or by physically adsorbing anionic groups on the surface of the abrasive.

The anionic abrasive used in the polishing composition according to some embodiments preferably exhibits a zeta potential of −5 mV or less at pH 7 or less (at any pH of pH 7 or less). From the viewpoint of improving the polishing removal rate, the zeta potential of the anionic abrasive is preferably −10 mV or less, more preferably −20 mV or less, still more preferably −30 mV or less, and particularly preferably −40 mV or less at pH 7 or less (at any pH of pH 7 or less). In addition, from the viewpoint of reducing defects, the zeta potential of the anionic abrasive is preferably −70 mV or more, more preferably −60 mV or more, and still more preferably −55 mV or more at pH 7 or less (at any pH of pH 7 or less).

The anionic abrasive used in the polishing composition according to some embodiments preferably exhibits a zeta potential of −5 mV or less in the polishing composition. It is preferable that the anionic abrasive exhibits a zeta potential of −5 mV or less in the polishing composition. From the viewpoint of improving the polishing removal rate, the zeta potential of the anionic abrasive is preferably −10 mV or less, more preferably −20 mV or less, still more preferably −30 mV or less, and particularly preferably −40 mV or less in the polishing composition. In addition, from the viewpoint of reducing defects, the zeta potential of the anionic abrasive is preferably −70 mV or more, more preferably −60 mV or more, and still more preferably −55 mV or more in the polishing composition.

Since the anionic abrasive has a zeta potential in such a range, it is possible to suppress defects such as scratches that may occur on the surface of the object to be polished after polishing using the polishing composition while improving the polishing removal rate for hafnium oxide.

Here, the zeta potential of the anionic abrasive is calculated by providing ELS-Z2 manufactured by OTSUKA ELECTRONICS CO., LTD with a measurement object containing the anionic abrasive, performing a measurement by a laser Doppler method (electrophoretic light scattering measurement method) using a flow cell at a measurement temperature of 25° C., and analyzing the obtained data by a Smoluchowski equation.

The zeta potential of the anionic abrasive in the polishing composition is calculated by providing ELS-Z2 manufactured by OTSUKA ELECTRONICS CO., LTD with the polishing composition, performing a measurement by a laser Doppler method (electrophoretic light scattering measurement method) using a flow cell at a measurement temperature of 25° C., and analyzing the obtained data by a Smoluchowski equation.

From the viewpoint of the effect of the present invention, preferred examples of the anionic abrasive include, but are not particularly limited to, cerium oxide abrasive grains, anionically modified silicon oxide abrasive grains, and the like. In one embodiment of the present invention, preferably, the anionic abrasive contains at least one selected from the group consisting of anionically modified silicon oxide abrasive grains and cerium oxide abrasive grains. It is preferable that the anionic abrasive contains anionically modified silicon oxide abrasive grains, cerium oxide abrasive grains, or a combination thereof. In an embodiment of the present invention, the silicon oxide abrasive grains used for constituting the above anionically modified silicon oxide abrasive grains preferably contain colloidal silica (colloidal silica particles). In a case where the anionic abrasive contains anionically modified silicon oxide abrasive grains, the mass ratio of the anionically modified silicon oxide abrasive grains to the entire abrasive particles of the anionic abrasive, that is, the mass ratio of the anionically modified silicon oxide abrasive grains to the total mass of the anionic abrasive is 80 mass % or more, 90 mass % or more, 95 mass % or more, 96 mass % or more, 97 mass % or more, 98 mass % or more, 99 mass % or more, or 100 mass %.

Any colloidal silica may be used as long as it is commonly used in the technical field of CMP. Examples of the usable colloidal silica include colloidal silica prepared using water glass (Na silicate) as a raw material by an ion exchange method, colloidal silica produced by an alkoxide method, and the like. The above alkoxide method colloidal silica is colloidal silica manufactured by a hydrolysis condensation reaction of alkoxysilane. The colloidal silica can be used singly or in combination of two or more kinds thereof. The colloidal silica used in examples described later was prepared by an alkoxide method.

In normal colloidal silica, since the value of zeta potential is close to zero under acidic conditions, silica particles do not electrically repel each other under acidic conditions and are likely to aggregate. On the other hand, by surface-modifying the colloidal silica so that the zeta potential of the colloidal silica has a relatively large positive value or negative value even under acidic conditions, the colloidal silica strongly repels each other and is well dispersed even under acidic conditions, so that the storage stability of the polishing composition is improved. It is preferable that the anionically modified silicon oxide abrasive grains contain surface-modified colloidal silica.

As the surface-modified colloidal silica, for example, colloidal silica having an organic acid immobilized on a surface thereof, colloidal silica in which a metal such as aluminum, titanium, or zirconium, or an oxide thereof is doped on the surface, or the like can be used.

In one embodiment of the present invention, the colloidal silica contained in the polishing composition is preferably colloidal silica in which an organic acid is immobilized on the surface of silica particles (colloidal silica having an organic acid immobilized on a surface thereof). The colloidal silica having an organic acid immobilized on a surface thereof tends to have a larger absolute value of zeta potential in the polishing composition than normal colloidal silica having no organic acid immobilized thereon. Therefore, it is easy to adjust the zeta potential of the colloidal silica in the polishing composition to a range of −5 mV or less. In some preferred embodiments, the anionically modified silicon oxide abrasive grains contain colloidal silica having an organic acid immobilized on a surface thereof.

Incidentally, the zeta potential of the colloidal silica can be controlled to fall within a desired range, for example, using an acid described later as a pH adjusting agent.

The organic acid is immobilized on the surface of the colloidal silica by chemically bonding a functional group of the organic acid to the surface of the colloidal silica. The immobilization of the organic acid on the colloidal silica is not achieved only by simply allowing the colloidal silica and the organic acid to coexist. Specific examples of the above organic acid include a sulfonic acid, a carboxylic acid, a sulfinic acid, and a phosphonic acid. Among them, from the viewpoint of easy manufacture, the colloidal silica having an organic acid immobilized on a surface thereof is preferably colloidal silica having a sulfonic acid or a carboxylic acid immobilized on a surface thereof, and more preferably colloidal silica having a sulfonic acid immobilized on a surface thereof. In some preferred embodiments, the anionically modified silicon oxide abrasive grains contain colloidal silica having sulfonic acid immobilized on a surface thereof.

The sulfonic acid can be immobilized on colloidal silica by, for example, the method described in “Sulfonic acid-functionalized silica through quantitative oxidation of thiol groups”, Chem. Commun. 246-247 (2003). Specifically, a silane coupling agent having a thiol group such as 3-mercaptopropyltrimethoxysilane is coupled to the colloidal silica, and then the thiol group is oxidized with hydrogen peroxide, whereby the colloidal silica having sulfonic acid immobilized on a surface thereof can be obtained. The colloidal silica having sulfonic acid immobilized on a surface thereof used in examples described later was produced by the above method.

The carboxylic acid can be immobilized on colloidal silica by, for example, the method described in “Novel Silane Coupling Agents Containing a Photolabile 2-Nitrobenzyl Ester for Introduction of a Carboxy Group on the Surface of Silica Gel”, Chemistry Letters, 3, 228-229 (2000). Specifically, by coupling a silane coupling agent containing a photoreactive 2-nitrobenzyl ester to colloidal silica and then irradiating the colloidal silica with light, colloidal silica having a carboxylic acid immobilized on a surface thereof can be obtained.

In some preferred embodiments, the anionic abrasive is a surface-modified colloidal silica. In some more preferred embodiments, the anionic abrasive is colloidal silica having an organic acid immobilized on a surface thereof. In some further preferred embodiments, the anionic abrasive is colloidal silica having sulfonic acid immobilized on a surface thereof.

The lower limit of the true specific gravity of silica (in the case of surface-modified silica, silica prior to surface modification) constituting the silicon oxide abrasive grains is not particularly limited, but is preferably 1.5 or more, more preferably 1.6 or more, and still more preferably 1.7 or more. As the true specific gravity of silica increases, the polishing rate tends to increase. From such a viewpoint, silica (silica particles) having a true specific gravity of 2.0 or more (for example, 2.1 or more) is particularly preferable. The upper limit of the true specific gravity of silica (in the case of surface-modified silica, silica prior to surface modification) is not particularly limited, but is typically 2.3 or less, for example, 2.2 or less. As the true specific gravity of silica, a measured value by a liquid replacement method using ethanol as a replacement liquid can be adopted. Note that the true specific gravity is a value that can vary depending on the production method of silica or the like. The true specific gravity of silica (silica prior to surface modification) used in examples described later was 1.88.

The average primary particle size of the abrasive grains contained in the anionic abrasive is not particularly limited. The average primary particle size of the abrasive grains contained in the anionic abrasive represents the average primary particle size of the abrasive grains constituting the anionic abrasive. For example, it can be appropriately selected from a range of about 5 to 200 nm, a range of about 5 to 100 nm, and the like. From the viewpoint of improving the anti-bulging property, the average primary particle size of the abrasive grains contained in the anionic abrasive is preferably 5 nm or more, more preferably 7 nm or more, and still more preferably 10 nm or more. In some embodiments, the average primary particle size of the abrasive grains contained in the anionic abrasive may be 15 nm or more, 20 nm or more, 25 nm or more, or 30 nm or more. In addition, from the viewpoint of preventing the occurrence of scratches, the average primary particle size of the abrasive grains contained in the anionic abrasive is usually advantageously 200 nm or less, preferably 150 nm or less, and more preferably 100 nm or less. In some embodiments, the average primary particle size of the abrasive grains contained in the anionic abrasive may be 90 nm or less, 80 nm or less, 70 nm or less, 60 nm or less, 50 nm or less, 45 nm or less, 40 nm or less, or 39 nm or less. As for the average primary particle size of the abrasive grains, first, the specific surface area of the abrasive grains is measured by a BET (Brunauer-Emmett-Teller) method, and the value of the average primary particle size of the abrasive grains can be calculated based on the measured specific surface area. The calculation was performed as described above in examples described later.

The average secondary particle size of the abrasive grains contained in the anionic abrasive is not particularly limited. The average secondary particle size of the abrasive grains contained in the anionic abrasive represents the average secondary particle size of the abrasive grains constituting the anionic abrasive. The average secondary particle size of the abrasive grains contained in the anionic abrasive is preferably 25 nm or more, more preferably 30 nm or more, and still more preferably 35 nm or more. In some embodiments, the average secondary particle size of the abrasive grains contained in the anionic abrasive may be 40 nm or more, 45 nm or more, 50 nm or more, 55 nm or more, 60 nm or more, 65 nm or more, or 66 nm or more. As the average secondary particle size of the abrasive grains contained in the anionic abrasive increases, the polishing removal rate for the object to be treated (for example, an object to be treated containing a hafnium oxide material) increases. The average secondary particle size of the abrasive grains contained in the anionic abrasive is preferably 300 nm or less, more preferably 260 nm or less, and still more preferably 220 nm or less. In some embodiments, the average secondary particle size of the abrasive grains contained in the anionic abrasive may be 200 nm or less, 180 nm or less, 160 nm or less, 140 nm or less, 120 nm or less, 100 nm or less, 90 nm or less, 80 nm or less, 75 nm or less, or 74 nm or less. As the average secondary particle size of the abrasive grains contained in the anionic abrasive decreases, it becomes possible to easily obtain a polished surface with less scratches when polishing the object to be polished using the polishing composition. The value of the average secondary particle size of the abrasive grains can be measured by a suitable method, for example, a laser light scattering method. The calculation was performed as described above in examples described later.

The shape of the abrasive grains (the outer shape of the primary particle) contained in the anionic abrasive is not particularly limited. The shape of the abrasive grains (the outer shape of the primary particle) contained in the anionic abrasive represents the shape of the abrasive grains (outer shape of primary particle) constituting the anionic abrasive. The shape of the abrasive grains contained in the anionic abrasive may be spherical or non-spherical. Specific examples of the non-spherical particle include, for example, a peanut shape, that is, a peanut shell shape, a cocoon shape, a protruding shape such as a kompeito-shape, a rugby ball shape, and the like. In examples described later, a cocoon shape was used. By using abrasive grains having such a shape, there is an effect of improving the polishing removal rate.

The average aspect ratio of the abrasive grains contained in the anionic abrasive is not particularly limited. The average aspect ratio of the abrasive grains contained in the anionic abrasive represents the average aspect ratio of the abrasive grains constituting the anionic abrasive. The average aspect ratio of the abrasive grains contained in the anionic abrasive is 1.0 or more in principle, and can be, for example, 1.05 or more or 1.1 or more. Increasing the average aspect ratio generally tends to improve the anti-bulging property. In addition, the average aspect ratio of the abrasive grains contained in the anionic abrasive is preferably 3.0 or less, and more preferably 2.0 or less, from the viewpoint of reducing scratches, improving polishing stability, and the like. In some embodiments, the average aspect ratio of the abrasive grains contained in the anionic abrasive may be, for example, 1.5 or less, 1.4 or less, or 1.3 or less. The average aspect ratio of the abrasive grains contained in the anionic abrasive used in examples described later was 1.24. The average aspect ratio of the abrasive grains is an average of values obtained by taking a minimum rectangle circumscribing the image of the abrasive grain particle by a scanning electron microscope (product name: SU8000, manufactured by Hitachi High-Tech Corporation) and dividing the length of the long side of the rectangle by the length of the short side of the same rectangle, and can be evaluated using general image analysis software. The calculation was performed as described above in examples described later.

In some embodiments, as the abrasive grains contained in the anionic abrasive (the abrasive grains constituting the anionic abrasive), for example, those in which the ratio of the volume of the particles having an aspect ratio of 1.2 or more to the total volume of the abrasive grains contained in the anionic abrasive is 50% or more can be adopted. The above volume ratio can also be, for example, 60% or more. In a case where the value of the above volume ratio is 50% or more, more specifically 60% or more, the anti-bulging property by the mechanical action of the abrasive grains can be further improved because the abrasive particles contain a relatively large amount of particles having a size and an aspect ratio particularly effective for the anti-bulging.

The content of the anionic abrasive is not particularly limited, and can be appropriately set according to the purpose. The content of the anionic abrasive with respect to the total mass of the polishing composition may be, for example, 0.1 mass % or more, 0.5 mass % or more, 1 mass % or more, or 1.5 mass % or more. Increasing the content of the anionic abrasive generally tends to improve the anti-bulging properties. In some embodiments, the content of the anionic abrasive relative to the total mass of the polishing composition may be 0.2 mass % or more, 0.3 mass % or more, 0.4 mass % or more, or 0.45 mass % or more. In addition, in some embodiments, the content of the anionic abrasive relative to the total mass of the polishing composition may be, for example, 15 mass % or less, 10 mass % or less, 7 mass % or less, 5 mass % or less, 4 mass % or less, 3.5 mass % or less, 3 mass % or less, or 2.5 mass % or less from the viewpoint of scratch prevention and saving of the use amount of the anionic abrasive. These contents can be preferably applied to, for example, the content in the polishing liquid (working slurry) supplied to the object to be polished.

### [(b) Nitrogen-Containing Additive]

The polishing composition according to the present aspect contains a specific nitrogen-containing additive. Surprisingly, using a specific nitrogen-containing additive in the polishing composition according to the present aspect, the removal rate of hafnium oxide by the polishing composition can be improved. Although not limited by theory, it is presumed that at least a part of the reason is that the unshared electron pair of the nitrogen atom in the nitrogen-containing additive is relatively stabilized, and a complex with hafnium is easily formed.

The usable nitrogen-containing additive contains at least one selected from the group consisting of the following (i), the following (ii), and the following (iii);
(i) a compound selected from the group consisting of a guanidine compound represented by Formula (I) below, an amidine compound represented by Formula (II) below, and salts thereof;
(ii) cyclic amino acids; and
(iii) a sulfonic acid compound having an amino group.

That is, the usable nitrogen-containing additive contains at least one selected from the group consisting of a guanidine compound represented by Formula (I) below, a salt of a guanidine compound represented by Formula (I) below, an amidine compound represented by Formula (II) below, a salt of an amidine compound represented by Formula (II) below, a cyclic amino acid, and a sulfonic acid compound having an amino group.

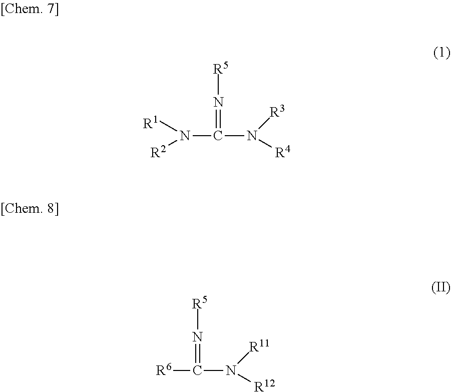

In Formula (I) above and Formula (II) above,
R¹, R², R³, R⁴, R¹¹ and R¹² are each independently a hydrogen atom, a cyano group, a nitro group (—NO₂), a nitroso group (—N═O), an amino group, an aminoalkyl group (a group in which at least one hydrogen atom of an alkyl group is substituted with an amino group), an alkyl group, an alkoxy group, an aryl group, a heterocyclic group, a —C(═O)-alkyl group, or a —C(═O)—O-alkyl group,
R⁶ is a hydrogen atom, a cyano group, a nitro group, a nitroso group, an aminoalkyl group, an alkyl group, an alkoxy group, an aryl group, a heterocyclic group, a —C(═O)-alkyl group, or a —C(═O)—O-alkyl group,
the aryl group or the heterocyclic group may be optionally substituted with one or more groups independently selected from a nitro group, a nitroso group, an amino group, or an alkyl group, and
R⁵'s are each independently a hydrogen atom, an alkyl group, or an alkoxy group.

Here, the phrase “the aryl group or the heterocyclic group is optionally substituted with one or more groups independently selected from a nitro group, a nitroso group, an amino group, or an alkyl group.” means that the aryl group or the heterocyclic group may be substituted with at least one substituent selected from the group consisting of a nitro group, a nitroso group, an amino group, and an alkyl group, or may be unsubstituted, and when a plurality of hydrogen atoms are substituted in the aryl group or the heterocyclic group, the kinds of substituents that substitute each hydrogen atom of the aryl group or the heterocyclic group may be the same or different. The number of nitro groups, nitroso groups, amino groups, and alkyl groups that substitute for the aryl group or the heterocyclic group is independently 0, 1, or 2 or more. Therefore, the number of at least one substituent selected from the group consisting of a nitro group, a nitroso group, an amino group, and an alkyl group that substitutes the aryl group or the heterocyclic group is 0, 1, or 2 or more.

In some embodiments, it is preferable that R¹, R² and R⁶ are each independently a hydrogen atom, an alkyl group, or an alkoxy group.

In Formula (I) above and Formula (II) above, the portion of the alkyl group or the alkylene group in the aminoalkyl group, the alkyl group, the alkoxy group, the —C(═O)-alkyl group, and the —C(═O)—O-alkyl group as R¹, R², R³, R⁴, R⁶, R¹¹, and R¹² may be a linear alkyl group, a branched alkyl group, a linear alkylene group or a branched alkylene group, and the number of carbon atoms thereof is not particularly limited, and is, for example, 1 to 20, preferably 1 to 10, more preferably 1 to 4, and still more preferably 1 or 2. The portion of the alkyl group in the alkyl group, and the alkoxy group as R⁵ may be a linear or branched alkyl group, and the number of carbon atoms thereof is not particularly limited, and is, for example, 1 to 20, preferably 1 to 10, more preferably 1 to 4, and still more preferably 1 or 2.

In Formula (I) above and Formula (II) above, the aryl group as R¹, R², R³, R⁴, R⁶, R¹¹, and R¹² may be a monocyclic aromatic hydrocarbon cyclic group containing 6 to 14 carbon atoms, a bicyclic aromatic hydrocarbon cyclic group containing 6 to 14 carbon atoms, or a tricyclic aromatic hydrocarbon cyclic group containing 6 to 14 carbon atoms. Examples thereof include, but are not limited to, a phenyl group, an indenyl group, a naphthyl group, a fluorenyl group, an anthracenyl group, a phenanthrenyl group, and groups similar thereto. It is preferably a phenyl group. In some embodiments, in Formula (I) above and Formula (II) above, the aryl group as R¹, R², R³, R⁴, R⁶, R¹¹ and R¹² may each independently be substituted or unsubstituted, and each independently is preferably substituted with one or more groups independently selected from a nitro group and a C₁₋₄ alkyl group (an alkyl group having 1 to 4 carbon atoms).

In Formula (I) above and Formula (II) above, the heterocyclic group as R¹, R², R³, R⁴, R⁶, R¹¹, and R¹² may be a saturated, partially saturated or unsaturated a 3- to 14-membered heterocyclic group constituted of carbon atoms and at least one heteroatom selected from N, O or S, is preferably a 4- to 10-membered heterocyclic group, is more preferably a 5- to 6-membered heterocyclic group. The heterocyclic group as R¹, R², R³, R⁴, R⁶, R¹¹, and R¹² is not particularly limited, but preferably has 1 to 4 heteroatoms, more preferably has 1 to 3 heteroatoms, and still more preferably has 1 to 2 heteroatoms. The heterocyclic group may be a monocyclic, bicyclic, or tricyclic ring system, may contain a fused ring (taken together with the other heterocyclic or aromatic hydrocarbon ring to form a fused ring), and may be substituted or unsubstituted. The kind of the hetero atom is preferably a nitrogen atom. Examples of the above-mentioned heterocyclic group include, but are not limited to, a pyrrolyl group, a pyrazolyl group, an imidazolyl group, a pyridinyl group, a pyridazinyl group, a pyrimidinyl group, a pyrazinyl group, a pyrrolidinyl group, a piperidinyl group, and a piperazinyl group.

In some embodiments, in Formula (I) above and Formula (II) above, the heterocyclic group as R¹, R², R³, R⁴, R⁶, R¹¹ and R¹² is preferably a 5- to 6-membered ring group containing 1 to 2 nitrogen atoms, and examples thereof include a pyrazolyl group, an imidazolyl group, and the like.

Examples of the salt of the guanidine compound represented by Formula (I) above and the salt of the amidine compound represented by Formula (II) above include a carbonate, a hydrochloride, a phosphate, a sulfate, a nitrate, a hydroiodide, and the like, respectively. However, since contamination of the substrate with a halide or the like is not desirable, a carbonate, a phosphate, a nitrate, or a sulfate is preferable.

In some preferred embodiments, the (b) nitrogen-containing additive is a guanidine compound represented by Formula (I), an amidine compound represented by Formula (II), or a salt thereof, and the salt is a carbonate, a hydrochloride, a sulfate, a phosphate, or a nitrate. In some more preferred embodiments, the (b) nitrogen-containing additive is a guanidine compound represented by Formula (I), and the R¹ and the R² are each independently a hydrogen atom, an alkyl group, or an alkoxy group.

Specific examples of the guanidine compound represented by Formula (I) above or a salt thereof include guanidine, a carbonate thereof (a carbonate of guanidine, guanidine carbonate), a hydrochloride thereof (a hydrochloride of guanidine), a phosphate thereof (a phosphate of guanidine), a sulfate thereof (a sulfate of guanidine), and a nitrate thereof (a nitrate of guanidine); guanidine hydroiodide; acetylguanidine; aminoguanidine, a carbonate thereof (a carbonate of aminoguanidine), a hydrochloride thereof (a hydrochloride of aminoguanidine) and a sulfate thereof (a sulfate of aminoguanidine); 1,3-diaminoguanidine and a hydrochloride thereof; 1-(tert-butoxycarbonyl)guanidine; dicyandiamide; 1,1-dimethylguanidine and a sulfate thereof; 1,1-diethylguanidine and a sulfate thereof; 1-methyl-3 nitroguanidine; 1-(2-methyl-5 nitrophenyl) guanidine and a nitrate thereof; nitroguanidine, nitrosoguanidine; octadecylguanidine and a hydrochloride thereof; and 1,1,3,3-tetramethylguanidine. These may be used singly or in combination of two or more kinds thereof. It is preferable that the guanidine compound represented by Formula (I) above or a salt thereof contains at least one compound selected from the group consisting of the compounds exemplified above. Among them, guanidine or a carbonate thereof (guanidine carbonate) is preferable from the viewpoint of improving the polishing removal rate of hafnium oxide, and guanidine is more preferable from the viewpoint of improving the selection ratio of hafnium oxide/silicon-based material.

Specific examples of the amidine compound represented by Formula (II) above or a salt thereof include acetamidine and a hydrochloride thereof; aminoacetamidine bromate; aminoacetamidine hydrobromide; and 1-amidinopyrazole and a hydrochloride thereof. Among them, aminoacetamidine bromate, aminoacetamidine hydrobromide, and 1-amidinopyrazole are preferable, and 1-amidinopyrazole is more preferable from the viewpoint of improving the polishing removal rate of hafnium oxide. These may be used singly or in combination of two or more kinds thereof. It is preferable that the amidine compound represented by Formula (II) above or a salt thereof contains at least one compound selected from the group consisting of the compounds exemplified above.

In some embodiments, the (ii) cyclic amino acid that can be used as a nitrogen-containing additive can have a structure represented by Formula (III) below.

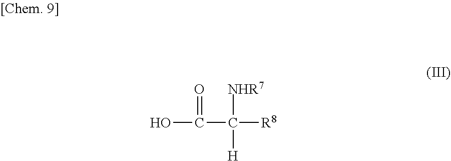

In Formula (III) above,
R⁷ is a hydrogen atom, an alkyl group or an alkoxy group, R⁸ is —(CH₂)ₚ-Q, p is 0, 1 or 2, Q is an aryl group or a heterocyclic group, and the aryl group or the heterocyclic group may be optionally substituted with one or more —OH's (hydroxy groups), or one or more or a hydroxyalkyl group (a group in which at least one hydrogen atom of an alkyl group is substituted with a hydroxy group), or
R⁷ and R⁸, and the carbon and nitrogen atoms bonded thereto together form a 5- to 6-membered heterocyclic ring (5-membered heterocyclic ring or 6-membered heterocyclic ring).

As aforementioned, R⁷, the nitrogen atom bonded to R⁷, R⁸ and the carbon atom bonded to R⁸ together may form a 5- to 6-membered heterocyclic ring.

In a case where R⁷ is a hydrogen atom, an alkyl group or an alkoxy group, R¹ is —(CH₂)ₚ-Q, p is 0, 1 or 2, and Q is an aryl group or a heterocyclic group, the aryl group or the heterocyclic group may be unsubstituted.

In Formula (III) above, the alkyl group and the alkoxy group as R⁷ may be linear or branched, and the number of carbon atoms thereof is not particularly limited and is, for example, 1 to 20, preferably 1 to 10, and more preferably 1 to 4.

The number of carbon atoms in the aryl group as Q is not particularly limited and is preferably 6 to 9, and examples of the aryl group as Q include phenyl, tolyl, isopropylphenyl, and the like. The heterocyclic group as Q is not particularly limited, and may be an aliphatic heterocyclic group or an aromatic heterocyclic group. Each of the aliphatic heterocyclic group and the aromatic heterocyclic group may be at least one selected from the group consisting of a monocyclic group and a condensed cyclic group. That is, the aliphatic heterocyclic group may be a monocyclic group or a condensed cyclic group, and the aromatic heterocyclic group may be a monocyclic group or a condensed cyclic group. The total number of atoms of the ring constituting the aliphatic heterocyclic group or the aromatic heterocyclic group is, for example, 3 to 15, preferably 3 to 12, more preferably 3 to 10, and still more preferably 3 to 6. The aliphatic heterocyclic group or the aromatic heterocyclic group may contain, as atoms constituting the ring, a nitrogen atom, an oxygen atom, or a sulfur atom in addition to a carbon atom. The number of heteroatoms is, for example, preferably 1 to 3, more preferably 1 or 2, and still more preferably 1.

In addition, the hydroxyalkyl group usable as the substituent of Q may be linear or branched, and the number of carbon atoms thereof is not particularly limited, and is, for example, 1 to 20, preferably 1 to 10, more preferably 1 to 4, and still more preferably 1 or 2.

Specific examples of the cyclic amino acid represented by Formula (III) above include phenylalanine, proline, tryptophan, tyrosine, and histidine. These may be used singly or in combination of two or more kinds thereof. It is preferable that the cyclic amino acid represented by Formula (III) above contains at least one compound selected from the group consisting of the compounds exemplified above. From the viewpoint of improving the polishing removal rate of hafnium oxide, the cyclic amino acid is preferably proline, tryptophan, or histidine, more preferably proline or histidine, still more preferably L-proline or L-histidine, and particularly preferably L-histidine.

In some embodiments, the (iii) sulfonic acid compound having an amino group that can be used as a nitrogen-containing additive is a sulfonic acid compound having a primary, secondary, or tertiary amide group (sulfonic acid compound having a primary amide group (primary amino group, —NH₂), a secondary amide group (secondary amino group, —NHR), or a tertiary amide group (tertiary amino group, —NRR′)). Here, R and R′ each independently represent an atom other than a hydrogen atom or an atomic group. From the viewpoint of improving the polishing removal rate of hafnium oxide, among them, a sulfonic acid compound having a primary amide group or a secondary amide group is preferable, and a sulfonic acid compound having a primary amide group is more preferable.

Specific examples of the sulfonic acid compound having a primary amide group include aminomethylsulfonic acid, taurine, and aminopropylsulfonic acid. Specific examples of the sulfonic acid compound having a secondary amide group include 2-methylaminoethanesulfonic acid and 2-[(2-aminoethyl) amino]ethanesulfonic acid. Specific examples of the sulfonic acid compound having a tertiary amide group include (4-(2-hydroxyethyl) piperazine-1-ethanesulfonic acid (HEPES), and N,N-Bis(2-hydroxyethyl)-2-aminoethanesulfonic acid (BES). These sulfonic acid compounds having an amino group may be used singly or in combination of two or more kinds thereof. It is preferable that the sulfonic acid compound having an amino group contains at least one compound selected from the group consisting of the compounds exemplified above.

In some embodiments, the (iii) sulfonic acid compound having an amino group that can be used as a nitrogen-containing additive has a structure represented by Formula (IV) below.

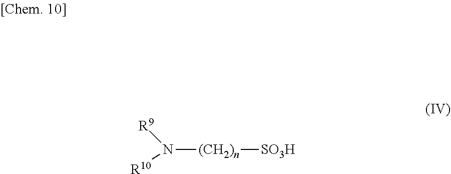

In Formula (IV) above,
n is 1, 2, 3, or 4.

Further, in Formula (IV) above,
R⁹ and R¹⁰ are each independently a hydrogen atom, an amino group, an aminoalkyl group (a group in which at least one hydrogen atom of an alkyl group is substituted with an amino group), an alkyl group or a hydroxyalkyl group (a group in which at least one hydrogen atom of an alkyl group is substituted with a hydroxy group), or R⁹ and R¹⁰, and the nitrogen atom bonded thereto (the nitrogen atom bonded to R⁹ and R¹⁰) together form a 5- to 6-membered heterocyclic ring (5-membered heterocyclic ring or 6-membered heterocyclic ring), and the 5- to 6-membered heterocyclic ring may be optionally substituted with one or more —OH's (hydroxy groups) or one or more hydroxyalkyl groups.

In a case where R⁹ and R¹⁰, and the nitrogen atom bonded thereto together form a 5- to 6-membered heterocyclic ring, the 5- to 6-membered heterocyclic ring may be unsubstituted.

In some embodiments, R⁹ and R¹⁰ are each independently a hydrogen atom, an aminoalkyl group, an alkyl group, or a hydroxyalkyl group; or
R⁹ and R¹⁰, and the nitrogen atom bonded thereto together form a 5- to 6-membered heterocyclic ring, and the 5- to 6-membered heterocyclic ring may be optionally substituted with one or more —OH's (hydroxy groups) or one or more hydroxyalkyl groups.

In Formula (IV) above, the portion of the alkyl group or alkylene group in the aminoalkyl group, the alkyl group, and the hydroxyalkyl group as R⁹ and R¹⁰ may be a linear alkyl group, a branched alkyl group, a linear alkylene group or a branched alkylene group, and the number of carbon atoms thereof is not particularly limited and is, for example, 1 to 20, preferably 1 to 10, more preferably 1 to 4, and still more preferably 1 or 2.

In a case where R⁹ and R¹⁰, and the nitrogen atom bonded thereto together form a 5- to 6-membered heterocyclic ring, the definition of the alkylene group in the hydroxyalkyl group as the substituent is the same as the alkylene group in the hydroxyalkyl group as R⁹ and R¹⁰.

In a case where R⁹ and R¹⁰, and the nitrogen atom bonded thereto together form a 5- to 6-membered heterocyclic ring, it is preferable that the hydroxyalkyl group as the substituent contains one hydroxy group. However, the number of hydroxy groups of the hydroxyalkyl group is not limited thereto, and may be two or more.

In a case where R⁹ and R¹⁰, and the nitrogen atom bonded thereto together form a 5- to 6-membered heterocyclic ring, examples of heterocyclic rings include, but are not limited to, a pyrrolyl group, a pyrazolyl group, an imidazolyl group, a pyridinyl group, a pyridazinyl group, a pyrimidinyl group, a pyrazinyl group, a pyrrolidinyl group, a piperidinyl group, and a piperazinyl group.

In some preferred embodiments, in Formula (IV),
n is 1, 2, 3, or 4,
R⁹ and R¹⁰ are each independently a hydrogen atom or a C₁₋₄ hydroxyalkyl group (a hydroxyalkyl group having 1 to 4 carbon atoms), or
R⁹ and R¹⁰, and the nitrogen atom bonded thereto together form a saturated 5- to 6-membered heterocyclic ring or an unsaturated 5- to 6-membered heterocyclic ring, containing 1 to 2 nitrogen atoms (a saturated 5- to 6-membered heterocyclic ring containing 1 to 2 nitrogen atoms or an unsaturated 5- to 6-membered heterocyclic ring containing 1 to 2 nitrogen atoms, preferably a 5- to 6-membered saturated heterocyclic ring containing 2 nitrogen atoms), and the saturated 5- to 6-membered heterocyclic ring or the unsaturated 5- to 6-membered heterocyclic ring may be optionally substituted with one or more —OH's or one or more C₁_4 hydroxyalkyl groups (hydroxyalkyl groups having 1 to 4 carbon atoms).

In some preferred embodiments, the nitrogen-containing additive is a guanidine compound represented by Formula (I) or a salt thereof, a cyclic amino acid represented by Formula (III), or a sulfonic acid compound having an amino group, represented by Formula (IV). In some more preferred embodiments, the nitrogen-containing additive is a guanidine compound represented by Formula (I), a cyclic amino acid represented by Formula (III), or a sulfonic acid compound having an amino group, represented by Formula (IV). In some further preferred embodiments, the nitrogen-containing additive is a guanidine compound represented by Formula (I); a cyclic amino acid represented by Formula (III); or a sulfonic acid compound having an amino group and not having a hydroxyalkyl group, represented by Formula (IV) (a compound not having a hydroxyalkyl group, represented by Formula (IV)). In some further preferred embodiments, the nitrogen-containing additive is a cyclic amino acid represented by Formula (III); or a sulfonic acid compound having an amino group and not having a hydroxyalkyl group, represented by Formula (IV) In some particularly preferred embodiments, the nitrogen-containing additive is a cyclic amino acid represented by Formula (III).

The content of the nitrogen-containing additive is not particularly limited, and can be appropriately set according to the purpose. The content of the nitrogen-containing additive with respect to the total mass of the polishing composition may be, for example, 0.005 mass % or more, 0.01 mass % or more, 0.03 mass % or more, or 0.05 mass % or more. In some embodiments, the content of the nitrogen-containing additive with respect to the total mass of the polishing composition may be 5 mass % or less, 1 mass % or less, 0.5 mass % or less, 0.2 mass % or less, or 0.15 mass % or less.

### [(c) Dispersing Medium]

The polishing composition according to the present aspect contains a dispersing medium. The dispersing medium functions as a dispersing medium or a solvent for dispersing or dissolving each component (for example, the anionic abrasive and the nitrogen-containing additive, and another optional additive (s) such as a surfactant and/or a pH adjusting agent) of the polishing composition. Examples of the dispersing medium include water, and an organic solvent. The dispersing medium can be used singly, or in mixture of two or more kinds thereof, but it is preferable that the dispersing medium contains water. In some preferred embodiments, the dispersing medium is water. However, from the viewpoint of preventing the inhibition of the action of each component, it is preferable to use water that does not contain impurities as much as possible. Specifically, pure water or ultrapure water from which impurity ions are removed with an ion exchange resin and then foreign substances are removed through a filter, or distilled water is preferable.

In some embodiments, the content ratio of water in the dispersing medium is 60 mass % or more, 70 mass % or more, 80 mass % or more, 90 mass % or more, 95 mass % or more, 96 mass % or more, 97 mass % or more, 98 mass % or more, 99 mass % or more, or 100 mass % with respect to the total mass of the dispersing medium.

### [(d) Surfactant]

The polishing composition according to some embodiments may contain a surfactant as necessary in addition to the above anionic abrasive, the above nitrogen-containing additive, and the above dispersing medium. The polishing composition according to some embodiments may further contain a surfactant or may not contain a surfactant. In some embodiments, since the surfactant in the polishing composition has an action of inhibiting polishing of silicon, the ratio (selection ratio) of the removal rate (polishing removal rate) of hafnium oxide to the removal rate (polishing removal rate) of the silicon-based material can be further improved. In addition, since the surfactant has an action of imparting hydrophilicity to the polished surface of the object to be polished after polishing, cleaning efficiency of the object to be polished after polishing can be improved, and adhesion of dirt and the like can be suppressed.

The surfactant is not particularly limited, and a known surfactant used in the field of polishing compositions can be used. Among them, a nonionic surfactant is preferable. In some embodiments, the surfactant preferably contains a nonionic surfactant. Specific examples of the nonionic surfactant include polyether, sorbitan fatty acid ester, glycerin fatty acid ester, polyoxyethylene fatty acid ester, polyoxyethylene alkylamine, and alkylalkanolamide. These may be used singly or in combination of two or more kinds thereof. It is preferable that the nonionic surfactant contains at least one compound selected from the group consisting of the compounds exemplified above. From the viewpoint of the storage stability of the polishing composition, it is preferable that the surfactant is a polyether.

Examples of the polyether include polyethylene glycol, polypropylene glycol, polytetramethylene glycol, polyethylene glycol alkyl ether, polyethylene glycol alkenyl ether, alkyl polyethylene glycol, alkyl polyethylene glycol alkyl ether, alkyl polyethylene glycol alkenyl ether, alkenyl polyethylene glycol, alkenyl polyethylene glycol alkyl ether, alkenyl polyethylene glycol alkenyl ether, polypropylene glycol alkyl ether, polypropylene glycol alkenyl ether, alkyl polypropylene glycol, alkyl polypropylene glycol alkyl ether, alkyl polypropylene glycol alkenyl ether, alkenyl polypropylene glycol, alkenyl polypropylene glycol alkyl ether, alkenyl polypropylene glycol alkyl ether, alkenyl polypropylene glycol alkenyl ether, polyoxyethylene alkylene diglyceryl ether, polyoxyethylene alkyl ether, polyoxyethylene alkylphenyl ether, polyoxyethylene polypropylene alkyl ether, polyglycerol, copolymers thereof, and the like. One kind of the above polyether may be used alone, or two or more kinds thereof may be used in combination. It is preferable that the polyether contains at least one compound selected from the group consisting of the compounds exemplified above. Among these polyethers, at least one selected from the group consisting of polyethylene glycol, polypropylene glycol, and polyglycerol is preferable. It is preferable that the surfactant is at least one selected from the group consisting of polyethylene glycol, polypropylene glycol, and polyglycerol. It is more preferable that the surfactant is at least one selected from the group consisting of polyethylene glycol and polypropylene glycol. It is still more preferable that the surfactant is polypropylene glycol.

According to some embodiments, the weight average molecular weight (Mw) of the polyether may be 100,000 or less, 10,000 or less, 1,000 or less, or 800 or less. In this specification, the weight average molecular weight is measured by a gel permeation chromatography (GPC) method using polyethylene glycol as a standard substance.

The upper limit of the content of the surfactant in the polishing composition according to some embodiments is preferably 5 mass % or less, more preferably 1 mass % or less, still more preferably 0.5 mass % or less, and particularly preferably 0.1 mass % or less with respect to the entire mass (total mass) of the polishing composition. The upper limit of the content of the surfactant with respect to the total mass of the polishing composition is preferably 5 mass % or less, more preferably 1 mass % or less, still more preferably 0.5 mass % or less, and particularly preferably 0.1 mass % or less. The lower limit of the content of the surfactant in the polishing composition according to some embodiments is preferably 0.001 mass % or more, more preferably 0.01 mass % or more, and still more preferably 0.03 mass % or more with respect to the entire mass (total mass) of the polishing composition. The lower limit of the content of the surfactant with respect to the total mass of the polishing composition is preferably 0.001 mass % or more, more preferably 0.01 mass % or more, and still more preferably 0.03 mass % or more with respect to the entire mass (total mass) of the polishing composition.

### [pH Adjusting Agent]

The polishing composition according to some embodiments can contain a pH adjusting agent. By using the pH adjusting agent, the pH of the polishing composition can be adjusted to a desired value. As the pH adjusting agent, a known acidic compound or basic compound may be used. The pH adjusting agent may be used singly or in combination of two or more kinds thereof.

The acidic compound may be an inorganic acid or an organic acid. Examples of the inorganic acid include hydrochloric acid (HCl), sulfuric acid (H₂SO₄), nitric acid (HNO₃), hydrofluoric acid (HF), boric acid (H₃BO₃), carbonic acid (H₂CO₃), hypophosphorous acid (H₃PO₂), phosphorous acid (H₃PO₃), and phosphoric acid (H₃PO₄). Among these inorganic acids, a preferred inorganic acid is hydrochloric acid, sulfuric acid, nitric acid, or phosphoric acid, and nitric acid is more preferred.

Examples of the organic acid include formic acid, acetic acid, propionic acid, butyric acid, valeric acid, 2-methylbutyric acid, n-hexanoic acid, 3,3-dimethylbutyric acid, 2-ethylbutyric acid, 4-methylpentanoic acid, n-heptanoic acid, 2-methylhexanoic acid, n-octanoic acid, 2-ethylhexanoic acid, benzoic acid, hydroxyacetic acid, salicylic acid, glyceric acid, oxalic acid, malonic acid, succinic acid, glutaric acid, adipic acid, pimelic acid, maleic acid, phthalic acid, malic acid, tartaric acid, citric acid, lactic acid, glyoxylic acid, 2-furancarboxylic acid, 2,5-furandicarboxylic acid, 3-furancarboxylic acid, 2-tetrahydrofuran carboxylic acid, methoxyacetic acid, methoxyphenylacetic acid, phenoxyacetic acid, and the like. A sulfonic acid such as methanesulfonic acid, ethanesulfonic acid, or isethionic acid (2-hydroxyethanesulfonic acid) may be used. Among these organic acids, a preferred organic acid is a monocarboxylic acid such as acetic acid; a dicarboxylic acid such as oxalic acid, malonic acid, succinic acid, glutaric acid, adipic acid, pimelic acid, maleic acid, phthalic acid, malic acid or tartaric acid; a tricarboxylic acid such as citric acid. As the organic acid, oxalic acid or maleic acid is more preferred.

Examples of the basic compound include a hydroxide of an alkali metal, a salt of an alkali metal, a hydroxide of a Group 2 element, a salt of a Group 2 element, a quaternary ammonium hydroxide, a quaternary ammonium salt, ammonia, an amine, and the like. Examples of the alkali metal include potassium and sodium. Ammonia is preferred.

It is preferable that the pH adjusting agent contains at least one compound selected from the group consisting of the compounds exemplified above.

The upper limit of the pH of the polishing composition according to the present aspect is less than 5. When the pH is too high (for example, in a case where the pH is 5 or more), the removal rate of hafnium oxide is deteriorated. The upper limit of the pH of the polishing composition is preferably 4.8 or less, more preferably 4.6 or less, and still more preferably 4.5 or less. The upper limit of the pH of the polishing composition may be, for example, 4.4 or less, 4.3 or less, 4.2 or less, 4.1 or less, 4.0 or less, 3.9 or less, 3.8 or less, 3.7 or less, 3.6 or less, 3.5 or less, 3.4 or less, 3.3 or less, 3.2 or less, 3.1 or less, or 3.0 or less. The lower limit of the pH of the polishing composition according to the present aspect is not particularly limited as long as it is 2 or more. However, in consideration of the safety of the production process and the burden of waste water treatment, the lower limit of the pH of the polishing composition is preferably 2.2 or more, and more preferably 2.5 or more. The lower limit of the pH may be 2.6 or more, 2.7 or more, 2.8 or more, 2.9 or more, or 3.0 or more. It is preferable that the pH of the polishing composition according to the present aspect is within a range of 2 or more and less than 5. pH in the present specification refers to pH at 25° C. The pH at 25° C. can be measured with a pH meter, and is a numerical value after the electrode is immersed in the polishing composition for 1 minute.

The content of the pH adjusting agent in the polishing composition is not particularly limited, and may be a content that achieves a desired pH.

[Another Component (s)]

As long as the effect of the present invention is not impaired, the polishing composition according to some embodiments may further contain another component(s) (in the present specification, a component(s) different from the components specifically described above is represented). The polishing composition according to some embodiments may further contain another component(s) or may not contain another component(s). Examples of another component(s) include an organic acid salt, an inorganic acid salt, an antiseptic agent, an antifungal agent, other well-known additives used in a polishing composition, and the like.

According to some embodiments, the content of the another component(s) is, for example, 10 mass % or less, 5 mass % or less, 4 mass % or less, 3 mass % or less, 2 mass % or less, 1 mass % or less, 0.5 mass % or less, 0.1 mass % or less, 0.05 mass % or less, 0.001 mass % or less, or 0.0005 mass % or less, with respect to the entire mass (total mass) of the components except the dispersing medium.

The polishing composition according to some preferred embodiments may be substantially composed of (a) an anionic abrasive, (b) a nitrogen-containing additive, (c) a dispersing medium, and a pH adjusting agent. The polishing composition according to some preferred embodiments may consist of, for example, only (a) an anionic abrasive, (b) a nitrogen-containing additive, and (c) a dispersing medium and a pH adjusting agent. “The polishing composition is substantially composed of X.” means that the total content of X exceeds 99 mass % (upper limit: 100 mass %) with respect to the total mass of the polishing composition. The polishing composition may consist of only X (the above total content=100 mass %).

The polishing composition according to some preferred embodiments may be substantially composed of (a) an anionic abrasive, (b) a nitrogen-containing additive, (c) a dispersing medium, (d) a surfactant, and a pH adjusting agent. The polishing composition according to some preferred embodiments may consist of, for example, only (a) an anionic abrasive, (b) a nitrogen-containing additive, (c) a dispersing medium, and (d) a surfactant and a pH adjusting agent. “The polishing composition is substantially composed of X.” means that the total content of X exceeds 99 mass % (upper limit: 100 mass %) with respect to the total mass of the polishing composition. The polishing composition may consist of only X (the above total content=100 mass %).

### [Form of Polishing Composition]

The polishing composition according to the present aspect may be of a one-liquid type or a multi-liquid type such as a two-liquid type. The polishing composition according to the present aspect may be in the form of a concentrated stock solution. In this case, the concentrated stock solution is diluted, for example, 2 to 10 times or more using a diluent such as water, and subjected to surface treatment.

### [Manufacturing Method of Polishing Composition]

The manufacturing method of the polishing composition according to the present aspect is not particularly limited. The polishing composition according to some embodiments can be manufactured, for example, by a method including mixing (a) an anionic abrasive, (b) a nitrogen-containing additive, (c) a dispersing medium, (d) a surfactant as necessary, a pH adjusting agent as necessary, and another component(s) as necessary. Details of each component are as described above. In some embodiments, when the polishing composition is a multi-liquid type including a two-liquid type, each liquid can be produced by a method including mixing components constituting each liquid.

### [Application]

It is preferable that the polishing composition according to the present aspect is used for treatment of a specific object. The treatment is not particularly limited, and examples thereof include surface treatment. Therefore, it can also be said that another embodiment of the present invention relates to use of the polishing composition for surface treatment. In some preferred embodiments, the surface treatment is at least one selected from the group consisting of a flattening treatment, a selective removal treatment and a cleaning treatment. In some preferred embodiments, the surface treatment is at least one selected from the group consisting of a polishing treatment, a selective removal treatment and a cleaning treatment. In some preferred embodiments, the polishing composition is used for polishing treatment and selective removal treatment.

### [Object to be Treated]

The object to be treated to be treated using the polishing composition according to the present aspect is not particularly limited, and examples thereof include a semiconductor material such as a wafer or a substrate, and an optical element such as a lens or a glass substrate. The object to be treated is preferably a material from which the hafnium oxide needs to be removed, an element from which the hafnium oxide needs to be removed, a material from which the hafnium oxide needs to be selectively removed, or an element from which the hafnium oxide needs to be selectively removed. The component of the object to be treated is also not particularly limited, but it is preferable that the object to be treated contains hafnium oxide. In some preferred embodiments, the object to be treated contains a silicon-based material, such as polysilicon, silicon germanium and/or TEOS, and hafnium oxide. It is preferable that the object to be treated contains hafnium oxide and at least one selected from the group consisting of polysilicon, silicon germanium and TEOS.

### <Surface Treatment Method (Polishing Method)>

Another aspect of the present invention can also be said to relate to a surface treatment method including a step of performing surface treatment on an object to be treated using the polishing composition according to the above aspect. The surface treatment using the polishing composition according to the above aspect is not particularly limited, and examples thereof include at least one selected from the group consisting of a flattening treatment, a selective removal treatment, and a cleaning treatment for the object to be treated. The surface treatment method using the polishing composition according to the above aspect is not particularly limited, but is preferably chemical mechanical polishing. In addition, the polishing process may be a polishing process including a single step or may be a polishing process including a plurality of steps. Examples of the polishing process including a plurality of steps include a process of performing a finish polishing step after a preliminary polishing step (rough polishing step), or a process of performing one or two or more secondary polishing steps after a primary polishing step and then performing a finish polishing step.

The surface treatment method according to some embodiments may be included in the semiconductor manufacturing method. Therefore, another aspect of the present invention can also be said to relate to a semiconductor manufacturing method including a process of performing the surface treatment method according to the above aspect.

### <Surface Treatment Apparatus (Polishing Apparatus)>

Another aspect of the present invention can also be said to relate to a surface treatment apparatus including a mechanism of performing surface treatment on an object to be treated using the polishing composition according to the above aspect. The surface treatment apparatus using the polishing composition according to the above aspect is not particularly limited, and examples thereof include a device that performs at least one selected from the group consisting of a flattening treatment, a selective removal treatment, and a cleaning treatment on an object to be treated, and the like.

As the surface treatment apparatus (polishing apparatus), a general polishing apparatus in which a holder for holding a substrate or the like having an object to be polished (object to be treated), a motor capable of changing the revolutions, and the like are attached, and which has a polishing table to which a polishing pad (polishing cloth) can be attached can be used.

As the polishing pad, a general nonwoven fabric; polyurethane; porous fluororesin; or the like can be used without particular limitation. It is preferable that the polishing pad is subjected to grooving such that the polishing composition is accumulated.

The polishing conditions are also not particularly limited, and for example, the rotation speed of the polishing table (number of revolutions of the polishing table) is preferably 10 to 500 rpm (60 rpm=1 s⁻¹), the rotation speed of the carrier (number of revolutions of the carrier) is preferably 10 to 500 rpm (60 rpm=1 s⁻¹), and the pressure (polishing pressure, polishing table pressure) applied to the substrate having the object to be polished (object to be treated) is preferably 0.1 to 10 psi (1 psi=6894.76 Pa). The method of supplying the polishing composition to the polishing pad is not particularly limited, and for example, a method of continuously supplying the polishing composition by a pump or the like is adopted. This supply amount is not limited, but it is preferable that the surface of the polishing pad is always covered with the polishing composition according to the above aspect.

After completion of the polishing, for example, the substrate may be washed with flowing water, and water droplets attached to the substrate may be removed by a spin dryer or the like and dried to obtain a substrate having a treated surface.

The surface treatment apparatus (polishing apparatus) according to some embodiments may be included in a semiconductor manufacturing facility. Therefore, it can be said that another aspect of the present invention relates to a semiconductor manufacturing facility including the surface treatment apparatus according to the above aspect.

### <Method for Selectively Removing Hafnium Oxide>

Another aspect of the present invention can also be said to relate to a method for selectively removing hafnium oxide using the polishing composition according to the above aspect, and preferred embodiments include, in particular, a method capable of selectively removing hafnium oxide with respect to a silicon-based material. Examples of the above silicon-based material include, but are not limited to, polysilicon, silicon germanium, TEOS, and the like. In some preferred embodiments, the above silicon-based material contains at least one selected from the group consisting of polysilicon, silicon germanium and TEOS.

According to the method for selectively removing hafnium oxide according to the present aspect, the purpose of selectively removing hafnium oxide while increasing the removal rate of hafnium oxide can be achieved. The method capable of selectively removing hafnium oxide according to the present aspect is not particularly limited as long as the polishing composition according to the above aspect is used, and may be performed together with a known production method and/or processing method for a semiconductor material, an optical element, or the like.

In some embodiments, the selection ratio of hafnium oxide/silicon-based material (polishing removal rate of hafnium oxide/polishing removal rate of silicon-based material) is, for example, 5 or more, 8 or more, 10 or more, or 12 or more, and preferably 20 or more, 50 or more, or 100 or more, under the conditions in the measurement of the polishing removal rate described in the examples.

In some embodiments, the selection ratio of hafnium oxide/polysilicon (the polishing removal rate of hafnium oxide/the polishing removal rate of polysilicon) is, for example, 5 or more, preferably 10 or more, 20 or more, 30 or more, 50 or more, 60 or more, 70 or more, or 80 or more, under the conditions in the measurement of the polishing removal rate described in the examples.

In some embodiments, the selection ratio of hafnium oxide/silicon germanium (the polishing removal rate of hafnium oxide/the polishing removal rate of silicon germanium) is, for example, 10 or more, preferably 15 or more, 20 or more, 50 or more, 80 or more, 100 or more, or 110 or more, under the conditions in the measurement of the polishing removal rate described in the examples.

In some embodiments, the selection ratio of hafnium oxide/TEOS (the polishing removal rate of hafnium oxide/the polishing removal rate of TEOS) is, for example, 8 or more, preferably 10 or more, 12 or more, or 20 or more, under the conditions in the measurement of the polishing removal rate described in the examples.

Although the embodiments of the present invention have been described in detail, this is illustrative and exemplary and not restrictive, and it is clear that the scope of the present invention should be interpreted by the appended claims.

### Examples

Hereinafter, the present invention will be further described with reference to examples and comparative examples, but the scope of the present invention is not limited to examples described later. In addition, unless otherwise specified in examples described later, the conditions of the polishing operation are all room temperature (20 to 25° C.)/relative humidity 40 to 50% RH.

### [Preparation of Polishing Composition]

In Examples 1 to 14 and Comparative Examples 1 to 9, polishing compositions were prepared by adjusting the pH to the values shown in Table 1 with a pH adjusting agent while mixing an abrasive, a nitrogen-containing additive, and a surfactant in a dispersing medium (ultrapure water) according to the compositions shown in Tables 1 and 2 below.

The pH of the polishing composition was confirmed by a pH meter (manufactured by HORIBA, Ltd., model number: F-73) (the temperature of the polishing composition at the time of pH measurement was 25° C.). In addition, “-” in Table 1 indicates that the component is not added. Each component and number in Table 1 will be described below.

Silica A: Colloidal silica having sulfonic acid immobilized on a surface thereof [Average primary particle size: 35 nm, average secondary particle size: 67 nm, zeta potential: −52 mV (pH=3 to 4), −53 mV (pH=4.5)],

Silica B: Colloidal silica with unmodified surface [Average primary particle size: 35 nm, average secondary particle size: 67 nm, zeta potential: +3 mV (pH=3)],

PPG: Polypropylene glycol [Weight average molecular weight: 400],

PG: Polyglycerol [Weight average molecular weight: 500],

HEPES: 4-(2-hydroxyethyl) piperazine-1-ethanesulfonic acid (compound of the following formula),

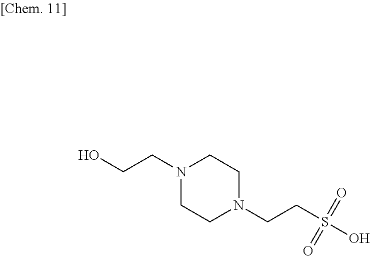 [SMILES: O=S(=O)(O)CCN1CCN(CCO)CC1]

BES: N,N-bis(2-hydroxyethyl)-2-aminoethanesulfonic acid (compound of the following formula),

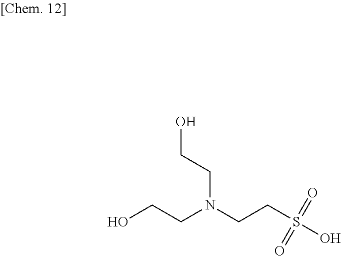 [SMILES: O=S(=O)(O)CCN(CCO)CCO]

BICINE: N,N-bis(2-hydroxyethyl)glycine (compound of the following formula),

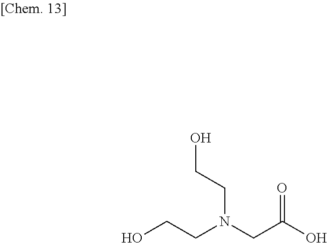 [SMILES: O=C(O)CN(CCO)CCO]

HfO₂: Hafnium oxide,

Poly-Si: Polysilicon,

SiGe: Silicon germanium,

TEOS: Silicon oxide produced from tetraethyl orthosilicate (also known as tetraethyl silicate) as a raw material, and RR [A/min]: Polishing removal rate.

### [Polishing Wafer]

The following four types of wafers were prepared.
A wafer (silicon wafer) on which a hafnium oxide film is laminated with a thickness of 400 Å,
A wafer (silicon wafer) on which a polysilicon film is laminated with a thickness of 5,000 Å,
A wafer (silicon wafer) on which a silicon germanium film is laminated of 1,500 Å, and
A wafer (silicon wafer) with a TEOS film laminated of 10,000 Å.

### [Polishing Conditions]

Each of the above polishing wafers was polished under the following conditions using the polishing composition obtained in the above preparation of the polishing composition.

Polishing apparatus: FREX 3005 H manufactured by EBARA CORPORATION,

Polishing pad: IC1010 manufactured by Rohm and Haas Company,

Dresser: A188 manufactured by 3M Corp,

Polishing time of hafnium oxide film: 10 seconds,

Polishing time of other films: 60 seconds,

Polishing table pressure: 140 hPa (2.03 psi)

Number of revolutions of polishing table: 100 rpm,

Supply rate of polishing composition: 300 ml/min,

Number of revolutions of dresser: 90 rpm,

Pressing force of the dress: 22 N,

Dressing time: 15 seconds, and

Flow rate of pure water: 2,000 ml/min.

### [Measurement of Polishing Removal Rate]

The film thickness before and after polishing was measured using a spectroscopic ellipso film thickness measurement device, and the polishing removal rate was calculated. Note that 1 Å=0.1 nm.

Spectroscopic ellipso film thickness measurement device: ASET-F5X manufactured by KLA-Tencor Corporation

TABLE 1

| | Components of polishing composition | | | | | | | | | | | | | | |
|---|---|---|---|---|---|---|---|---|---|---|---|---|---|---|---|
| | | | Nitrogen- | | | | | | | | | | | | |
| | | | containing | | | | | | Polishing removal rate | | | | | | |
| | Abrasive/ | | additive/ | | Surfactant/ | | pH | | (Å/min) | | | | Selection ratio | | |
| Ex- | content | | content | | content | | adjusting | | | Poly- | | | HfO₂/ | HfO₂/ | HfO₂/ |
| amples | (mass %) | | (mass %) | | (mass %) | | agent | pH | HfO₂ | Si | SiGe | TEOS | Poly-Si | SiGe | TEOS |
| 1 | Silica A | 2 | Guanidine | 0.1 | — | — | Nitric | 3.0 | 1335 | 105 | 96 | 57 | 13 | 14 | 23 |
| | | | | | | | acid | | | | | | | | |
| 2 | Silica A | 2 | Guanidine | 0.05 | — | — | Nitric | 3.0 | 1454 | 207 | 89 | 120 | 7 | 16 | 12 |
| | | | carbonate | | | | acid | | | | | | | | |
| 3 | Silica A | 2 | Guanidine | 0.07 | — | — | Nitric | 3.0 | 1252 | 230 | 108 | 129 | 5 | 12 | 10 |
| | | | carbonate | | | | acid | | | | | | | | |
| 4 | Silica A | 2 | Guanidine | 0.1 | — | — | Nitric | 3.0 | 1341 | 206 | 104 | 139 | 7 | 13 | 10 |
| | | | carbonate | | | | acid | | | | | | | | |
| 5 | Silica A | 2 | Guanidine | 0.15 | — | — | Nitric | 3.0 | 1354 | 162 | 90 | 169 | 8 | 15 | 8 |
| | | | carbonate | | | | acid | | | | | | | | |
| 6 | Silica A | 2 | Guanidine | 0.1 | PPG | 0.05 | Nitric | 3.0 | 1338 | 13 | 11 | 58 | 103 | 122 | 23 |
| | | | | | | | acid | | | | | | | | |
| 7 | Silica A | 2 | Guanidine | 0.1 | PPG | 0.05 | Nitric. | 4.0 | 1250 | 16 | 10 | 40 | 78 | 125 | 31 |
| | | | | | | | acid | | | | | | | | |
| 8 | Silica A | 2 | Guanidine | 0.1 | PPG | 0.05 | Nitric | 4.5 | 1153 | 18 | 8 | 28 | 64 | 144 | 41 |
| | | | | | | | acid | | | | | | | | |
| 9 | Silica A | 2 | L-histidine | 0.1 | PPG | 0.05 | Nitric | 3.0 | 1583 | 17 | 14 | 72 | 94 | 117 | 22 |
| | | | | | | | acid | | | | | | | | |
| 10 | Silica A | 2 | L-proline | 0.1 | PPG | 0.05 | Nitric | 3.0 | 1485 | 19 | 14 | 62 | 78 | 106 | 24 |
| | | | | | | | acid | | | | | | | | |
| 11 | Silica A | 2 | Taurine | 0.1 | PPG | 0.06 | Nitric | 3.0 | 1433 | 18 | 12 | 59 | 81 | 121 | 24 |
| | | | | | | | acid | | | | | | | | |
| 12 | Silica A | 2 | HEPES | 0.1 | PPG | 0.05 | Nitric: | 3.0 | 1243 | 14 | 10 | 52 | 89 | 124 | 24 |
| | | | | | | | acid | | | | | | | | |
| 13 | Silice A | 2 | BES | 0.1 | PPG | 0.05 | Nitric | 3.0 | 1087 | 12 | 7 | 48 | 91 | 155 | 23 |
| | | | | | | | acid | | | | | | | | |
| 14 | Silica A | 2 | Guanidine | 0.1 | PG | 0.05 | Nitric | 3.0 | 1025 | 36 | 17 | 135 | 28 | 22 | 8 |
| | | | carbonate | | | | acid | | | | | | | | |

TABLE 2

| | Components of polishing composition | | | | | | | | | | | | | | |
|---|---|---|---|---|---|---|---|---|---|---|---|---|---|---|---|
| | | | Nitrogen- | | | | | | | | | | | | |
| Com- | | | containing | | | | | | Polishing removal rate | | | | | | |
| parative | Abrasive/ | | additive/ | | Surfactant/ | | pH | | (Å/min) | | | | Selection ratio | | |
| Ex- | content | | content | | content | | adjusting | | | Poly- | | | HfO₂/ | HfO₂/ | HfO₂/ |
| amples | (mass %) | | (mass %) | | (mass %) | | agent | pH | HfO₂ | Si | SiGe | TEOS | Poly-Si | SiGe | TEOS |
| 1 | Silica | 2 | — | — | — | — | Nitric | 3.0 | 720 | 22 | 38 | 86 | 33 | 19 | 8 |
| | A | | | | | | acid | | | | | | | | |
| 2 | Silica | 2 | — | — | PPG | 0.05 | Nitric | 3.0 | 698 | 18 | 15 | 41 | 39 | 47 | 17 |
| | A | | | | | | acid | | | | | | | | |
| 3 | Silica | 2 | Guanidine | 0.1 | PPG | 0.05 | Nitric | 3.0 | 43 | 32 | 18 | 1071 | 1 | 2 | 0 |
| | B | | | | | | acid | | | | | | | | |
| 4 | Silica | 2 | Glycine | 0.1 | PPG | 0:05 | Nitric | 3.0 | 668 | 15 | 23 | 62 | 45 | 29 | 11 |
| | A | | | | | | acid | | | | | | | | |
| 5 | Silica | 2 | BICINE | 0.1 | PPG | 0.05 | Nitric | 3.0 | 634 | 19 | 12 | 57 | 33 | 53 | 11 |
| | A | | | | | | acid | | | | | | | | |
| 6 | Silica | 2 | L- | 0.1 | PPG | 0.05 | Nitric | 3.0 | 423 | 23 | 16 | 64 | 18 | 26 | 7 |
| | A | | aspartic | | | | acid | | | | | | | | |
| | | | acid | | | | | | | | | | | | |
| 7 | Silica | 2 | Arginine | 0.1 | PPG | 0.05 | Nitric | 3.0 | 708 | 16 | 15 | 73 | 44 | 47 | 10 |
| | A | | | | | | acid | | | | | | | | |
| 8 | Silica | 2 | Guanidine | 0.1 | PPG | 0.05 | Nitric | 5.0 | 743 | 20 | 8 | 28 | 37 | 93 | 27 |
| | A | | | | | | 3cid | | | | | | | | |
| 9 | Silica | 2 | Guanidine | 0.1 | PPG | 0.05 | Nitric | 6.0 | 214 | 23 | 6 | 20 | 9 | 36 | 11 |
| | A | | | | | | acid | | | | | | | | |

As shown in Tables 1 and 2, from the comparison between Examples 1 to 5 and Comparative Example 1 and the comparison between Examples 6 to 14 and Comparative Example 2, it is found that the addition of the nitrogen-containing additive in the embodiment of the present invention contributes to the improvement of the polishing removal rate of hafnium oxide. In Comparative Examples 4 to 7, nitrogen-containing additives were added, but since they are not the nitrogen-containing additives in the embodiment of the present invention, the polishing removal rate of hafnium oxide could not be improved as compared with Examples 1 to 14. In addition, Example 6 and Comparative Example 3 are different from each other in the type of abrasive. In Example 6, since the abrasive in the embodiment of the present invention is used, the polishing removal rate of hafnium oxide can be improved. In addition, the polishing compositions of Examples 6 to 8 and Comparative Examples 8 and 9 have the same components, but in Comparative Examples 8 and 9 in which the pH was out of the pH range in the embodiment of the present invention, the polishing removal rate of hafnium oxide could not be improved.

In addition, as shown in Table 1, as can be seen from the experimental results of Examples 6 to 14, when polishing is performed using a polishing composition containing a surfactant, the polishing removal rate of the silicon-based material (polysilicon, silicon germanium, TEOS, or the like) is further reduced, and the hafnium oxide is polished at a higher removal rate than the silicon-based material, whereby the effect of selectively removing the hafnium oxide can be achieved better.

The present application is based on Japanese Patent Application No. 2023-148913 filed on Sep. 14, 2023, the disclosure content of which is incorporated herein by reference in its entirety.

What is claimed is:

1. A polishing composition comprising: (a) an anionic abrasive; (b) a nitrogen-containing additive; and (c) a dispersing medium, wherein
a pH of the polishing composition is 2 or more and less than 5, and
the (b) nitrogen-containing additive contains at least one selected from the group consisting of the following (i), the following (ii), and the following (iii);
(i) a compound selected from the group consisting of a guanidine compound represented by Formula (I) below, an amidine compound represented by Formula (II) below, and salts thereof; 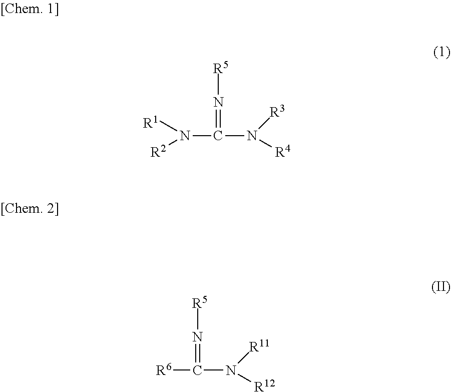
wherein
R¹, R², R³, R⁴, R¹¹ and R¹² are each independently a hydrogen atom, a cyano group, a nitro group, a nitroso group, an amino group, an aminoalkyl group, an alkyl group, an alkoxy group, an aryl group, a heterocyclic group, a —C(═O)-alkyl group, or a —C(═O)—O-alkyl group,
R⁶ is a hydrogen atom, a cyano group, a nitro group, a nitroso group, an aminoalkyl group, an alkyl group, an alkoxy group, an aryl group, a heterocyclic group, a —C(═O)-alkyl group, or a —C(═O)—O-alkyl group,
the aryl group or the heterocyclic group may be optionally substituted with one or more groups independently selected from a nitro group, a nitroso group, an amino group, or an alkyl group, and
R⁵'s are each independently a hydrogen atom, an alkyl group, or an alkoxy group;
(ii) a cyclic amino acid; and
(iii) a sulfonic acid compound having an amino group.

2. The polishing composition according to claim 1, wherein the R¹, the R², and the R⁶ are each independently a hydrogen atom, an alkyl group, or an alkoxy group.

3. The polishing composition according to claim 1, wherein the (b) nitrogen-containing additive is the guanidine compound represented by the Formula (I), the amidine compound represented by the Formula (II), or a salt thereof, and the salt is a carbonate, a hydrochloride, a sulfate, a phosphate, or a nitrate.

4. The polishing composition according to claim 1, wherein the (b) nitrogen-containing additive is the guanidine compound represented by the Formula (I), and the R¹ and the R² are each independently a hydrogen atom, an alkyl group, or an alkoxy group.

5. The polishing composition according to claim 1, wherein the (ii) cyclic amino acid has a structure represented by Formula (III) below: 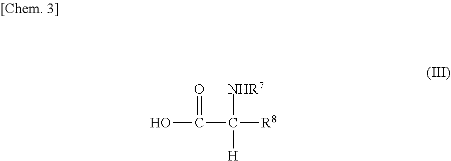
wherein
R⁷ is a hydrogen atom, an alkyl group or an alkoxy group, R⁸ is —(CH₂)ₚ-Q, p is 0, 1 or 2, Q is an aryl group or a heterocyclic group, and the aryl group or the heterocyclic group may be optionally substituted with one or more —OH's or one or more hydroxyalkyl groups, or
R⁷ and R⁸, and the carbon and nitrogen atoms bonded thereto together form a 5- to 6-membered heterocyclic ring.

6. The polishing composition according to claim 1, wherein the (ii) cyclic amino acid is proline, tryptophan, or histidine.

7. The polishing composition according to claim 1, wherein the (iii) sulfonic acid compound having an amino group is a sulfonic acid compound having a primary amide group, a secondary amide group, or a tertiary amide group.

8. The polishing composition according to claim 7, wherein the (iii) sulfonic acid compound having an amino group has a structure represented by Formula (IV) below; 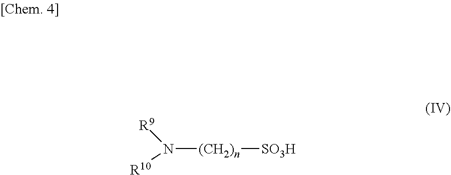
wherein
n is 1, 2, 3, or 4,
R⁹ and R¹⁰ are each independently a hydrogen atom, an amino group, an aminoalkyl group, an alkyl group, or a hydroxyalkyl group, or
R⁹ and R¹⁰, and the nitrogen atom bonded thereto together form a 5- to 6-membered heterocyclic ring and the 5- to 6-membered heterocyclic ring may be optionally substituted with one or more —OH's or one or more hydroxyalkyl groups.

9. The polishing composition according to claim 1, wherein the (a) anionic abrasive is surface-modified colloidal silica.

10. The polishing composition according to claim 1, wherein the (c) dispersing medium is water.

11. The polishing composition according to claim 1, further comprising: (d) a surfactant.

12. The polishing composition according to claim 11, wherein the (d) surfactant is polyether.

13. The polishing composition according to claim 11, wherein the (d) surfactant is at least one selected from the group consisting of polyethylene glycol, polypropylene glycol, polyglycerol, and copolymers thereof.

14. The polishing composition according to claim 1, wherein a content of the (a) anionic abrasive with respect to a total mass of the polishing composition is 0.1 to 15 mass %.

15. The polishing composition according to claim 1, wherein a content of the (b) nitrogen-containing additive with respect to a total mass of the polishing composition is 0.005 to 5 mass %.

16. A surface treatment method comprising: a process of performing a surface treatment on an object to be treated using the polishing composition according to claim 1.
